(19) United States
(12) Patent Application Publication
(10) Pub. No.: US 2007/0272930 A1
(43) Pub. Date: Nov. 29, 2007

(54) LIGHT-EMITTING DIODE PACKAGE

(76) Inventors: Huan-Che Tseng, Tao-Yung Hsien (TW); Way-Jze Wen, Tao-Yung Hsien (TW); Shyi-Ming Pan, Tao-Yung Hsien (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/308,926

(22) Filed: May 26, 2006

(51) Int. Cl. H01L 33/00

(52) U.S. Cl. 257/79

(57) ABSTRACT

A light-emitting diode package (LED package) includes a LED and a carrier. The LED includes a substrate, a semiconductor layer, a first electrode and a second electrode. The semiconductor layer is located on a surface of the substrate and has a rough surface. The semiconductor layer includes a first-type doped semiconductor layer, a second-type doped semiconductor layer and a light-emitting layer disposed between the two doped semiconductor layers. The first electrode and the second electrode are disposed on and electrically coupled the first-type doped semiconductor layer and the second-type doped semiconductor layer, respectively. The carrier has a rough carrying surface and includes a first contact pad and a second contact pad disposed on the rough carrying surface. The first electrode and the second electrode of the LED face the carrier and are electrically coupled to the first contact pad and a second contact pad, respectively.

### BACKGROUND OF THE INVENTION

1. Field of Invention

The present invention relates to a semiconductor device structure, and particularly to a light-emitting diode package (LED package).

2. Description of the Related Art

The light-emitting diode (LED) formed by semiconductor material of the compound of the group III-V elements is a wide bandgap luminous component, which emits the light covering all wavebands of visible light. In recent years, following the progress towards high-chroma and extreme-brightness, LEDs have gained broader applications fields, such as mega-size outdoor display boards and traffic lights, and would even substitute tungsten lamps and mercury lights to become a future lighting source with energy-saving and environmentally friendly advantages.

The LED basic structure includes a semiconductor layer. The semiconductor layer comprises a P-type doped semiconductor layer, an N-type doped semiconductor layer and a light-emitting layer disposed between the P-type doped semiconductor layer and the N-type doped semiconductor layer. The luminous efficiency of a LED depends on the quantum efficiency of the light-emitting layer and the light extraction efficiency thereof. However, the semiconductor compound material of the group III-V elements has a higher refractive index, therefore the light emitted from the light-emitting layer tends to get total reflection (TR), such that most light radiates at the sides of the LED. In other words, the luminance in front direction of the LED cannot be advanced.

FIG. 1 is a conventional LED diagram. Referring to FIG. 1, a conventional LED 100 includes a substrate 110, a semiconductor layer 120, a conductive layer 130, a reflective layer 140 and two electrodes 150. The semiconductor layer 120 is located on the substrate 110, wherein the semiconductor layer 120 includes, sequentially from bottom up, an N-type doped semiconductor layer 122, a light-emitting layer 124 and a P-type doped semiconductor layer 126. The conductive layer 130 is located on the P-type doped semiconductor layer 126, the reflective layer 140 is located on the conductive layer 130 and the two electrodes 150 are located on the N-type doped semiconductor layer 122 and the reflective layer 140, respectively. The two electrodes 150 are electrically coupled to the N-type doped semiconductor layer 122 and the P-type doped semiconductor layer 126, respectively.

FIG. 2 is a schematic drawing of a conventional LED package. Referring to FIG. 2, in a conventional LED package 20, the above-mentioned LED 100 is electrically coupled to a carrier 200 through a flip-chip interconnecting technology. The two electrodes 150 of the LED 100 are electrically coupled to the carrier 200 via bumps 22. As a current is applied between the two electrodes 150, the light-emitting layer 124 would radiate light due to the flowing current. The light emitted from the light-emitting layer 124 would be reflected by the reflective layer 140 to emit on the reverse side of the electrodes 150, such that the light emitted from the light-emitting layer 124 would radiate externally to improve the light extraction efficiency of the LED 100.

From the above described it can be seen that in the prior art, a structure with a better reflection index is used to increase the light extraction efficiency of a LED. However, as the light emitted from the light-emitting layer is reflected by the reflective layer and then the most light travels through the semiconductor layer, the light could be absorbed by the semiconductor layer; therefore the light extraction efficiency of the LED is limited and can not be substantially advanced. Thus, how to effectively enable the light emitted from the light-emitting layer to be more fully transmitted externally to effectively improve the light extraction efficiency of the LED has become an important subject.

### SUMMARY OF THE INVENTION

Accordingly, the present invention is directed to provide a light-emitting diode package (LED package), wherein the LED has better light extraction efficiency.

As embodied and broadly described herein, the present invention provides a LED package, which includes a LED, a carrier and a reflective layer. The LED includes a substrate, a semiconductor layer, a first electrode and a second electrode. The semiconductor layer is disposed on the substrate and has a rough layer. Besides, the semiconductor layer includes a first-type doped semiconductor layer, a light-emitting layer and a second-type doped semiconductor layer, wherein the light-emitting layer is located between the first-type doped semiconductor layer and the second-type doped semiconductor layer. The first electrode is located on the first-type doped semiconductor layer and is electrically coupled to the first-type doped semiconductor layer, while the second electrode is located on the second-type doped semiconductor layer and is electrically coupled to the second-type doped semiconductor layer. The carrier has a first contact pad and a second contact pad disposed on a surface thereof. The first electrode and the second electrode of the LED face the carrier and are electrically coupled to the first contact pad and the second contact pad, respectively. The reflective layer is disposed on a surface of the carrier facing the LED.

In an embodiment of the present invention, the surface of the substrate is, for example, a rough surface.

In an embodiment of the present invention, the LED package further includes two bumps, which are disposed on the first electrode and the second electrode, respectively. The first electrode and the second electrode are electrically coupled to the first contact pad and the second contact pad via the bumps, respectively.

In an embodiment of the present invention, the LED package further includes solder materials disposed on the first electrode and the second electrode, wherein the first electrode and the second electrode are electrically coupled to the first contact pad and the second contact pad via the solder materials, respectively.

In an embodiment of the present invention, the LED package further includes a transparent conductive layer, which is disposed on the semiconductor layer, and the first electrode and the second electrode are located on the transparent conductive layer.

In an embodiment of the present invention, the material of the transparent conductive layer is, for example, indium tin oxide (ITO), indium zinc oxide (IZO), aluminum zinc oxide (AlznO), zinc oxide (ZnO), nickel oxide (NiO) or nickel gold alloy (NiAu).

In an embodiment of the present invention, the first-type doped semiconductor layer is located, for example, on the substrate, the light-emitting layer is located on the first-type doped semiconductor layer and the second-type doped semiconductor layer is located on the light-emitting layer.

In an embodiment of the present invention, the above-described first-type doped semiconductor layer can be a P-type doped semiconductor layer, while the second-type doped semiconductor layer can be an N-type doped semiconductor layer. Alternatively, the first-type doped semiconductor layer can be an N-type doped semiconductor layer, while the second-type doped semiconductor layer can be a P-type doped semiconductor layer.

In an embodiment of the present invention, a material of the substrate is, for example, sapphire, silicon carbide (6H—SiC or 4H—SiC), silicon (Si), zinc oxide (ZnO), gallium arsenide (GaAs), spinel (MgAl₂O₄) or a monocrystalline oxide with lattice constant close to that of nitride semiconductor.

In an embodiment of the present invention, the light-emitting layer is, for example, a multiple-quantum-well (MQW) light-emitting layer.

In an embodiment of the present invention, the carrier is, for example, a silicon substrate, an aluminum nitride substrate, a metal substrate, an alloy substrate or a ceramic substrate.

In an embodiment of the present invention, the carrier includes a lead frame, a print circuit board (PCB) or a plastic lead chip carrier (PLCC).

The present invention further provides another LED package, which is similar to the above-described LED package, except that on the carrier surface of the LED package, a rough carrying surface substitutes the above-described reflective layer.

In the LED package of the present invention, since both the semiconductor layer and the carrier have a rough surface, the light emitted from the light-emitting layer can be more fully transmitted externally and the light extraction efficiency of the LED is effectively advanced. In addition, the present invention further provides a LED package, wherein the semiconductor layer has a rough surface and the carrier has a reflective layer, such that extraction efficiency of the LED can be improved.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve for explaining the principles of the invention.

FIG. 1 is a conventional LED diagram.

FIG. 2 is a schematic drawing of a conventional LED package.

FIG. 3 is a LED diagram of a LED package according to an embodiment of the present invention.

FIG. 4 is a schematic drawing of a LED package according to an embodiment of the present invention.

FIG. 5 is a schematic drawing of a LED package according to another embodiment of the present invention.

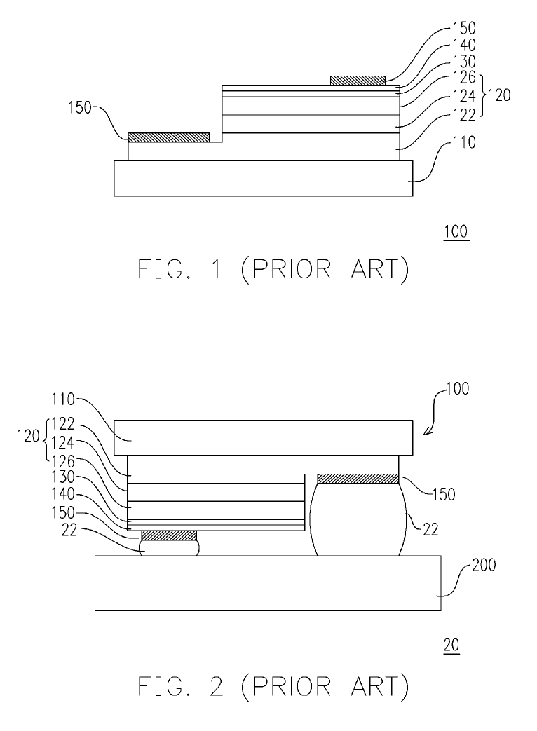

### DESCRIPTION OF THE EMBODIMENTS

The LED package of the present invention includes a LED and a carrier, wherein the LED is electrically coupled to the carrier through flip-chip interconnecting technology. In the embodiment, the LED can be a white LED chip, an ultraviolet LED chip or other LEDs suitable for emitting different color lights. The carrier can be a substrate or a lead frame. In the following, a LED package of an embodiment in the present invention is described in detail.

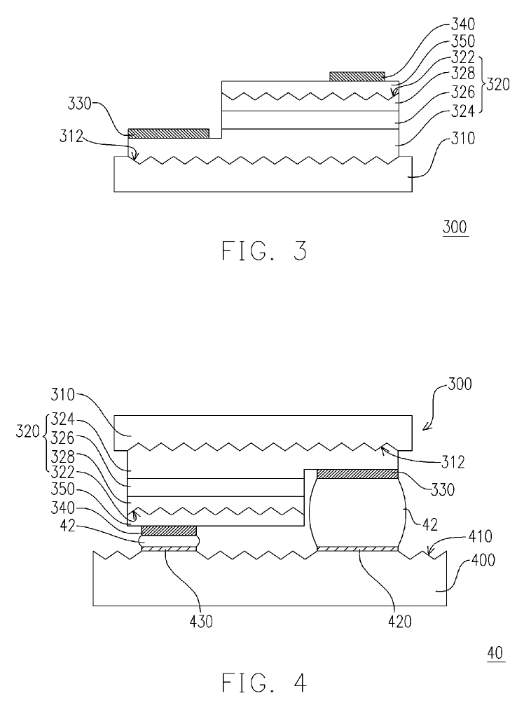

FIG. 3 is a LED diagram of a LED package according to an embodiment of the present invention. Referring to FIG. 3, the LED 300 of the present invention mainly includes a substrate 310, a semiconductor layer 320, a first electrode 330 and a second electrode 340. In the present embodiment, the semiconductor layer 320 is disposed on the substrate 310 and has a rough surface 322. In addition, the semiconductor layer 320 includes a first-type doped semiconductor layer 324, a light-emitting layer 326 and a second-type doped semiconductor layer 328. The light-emitting layer 326 is located between the first-type doped semiconductor layer 324 and the second-type doped semiconductor layer 328. The first electrode 330 is located on the first-type doped semiconductor layer 324 and is electrically coupled to the first-type doped semiconductor layer 324, while the second electrode 340 is located on the second-type doped semiconductor layer 328 and is electrically coupled to the second-type doped semiconductor layer 328.

Besides, the substrate 310 has, for example, a rough surface 312, formed by performing a surface treatment on the substrate 310. The surface treatment can be, for example, lapping the surface to form an irregular surface on the substrate 310, or etching the surface in a reactive ion etching (RIE) process to form a regularly or periodically varying rough surface on the substrate 310. The present invention does not limit the surface texture of the rough surface. The material of the substrate 310 can be sapphire, silicon carbide (6H—SiC or 4H—SiC), silicon (Si), zinc oxide (ZnO), gallium arsenide (GaAs), spinel (MgAl₂O₄) or a monocrystalline oxide with lattice constant close to that of nitride semiconductor. The rough surface 322 is formed in the same processing as that for the rough surface 312.

In the embodiment, the first-type doped semiconductor layer 324 is disposed, for example, on the substrate 310, the light-emitting layer 326 is disposed, for example, on the first-type doped semiconductor layer 324 and the second-type doped semiconductor layer 328 is disposed, for example, on the light-emitting layer 326, wherein the light-emitting layer 326 is, for example, a multiple-quantum-well (MQW). Besides, the rough surface 322 of the semiconductor layer 320 is disposed, for example, on the second-type doped semiconductor layer 328.

Further, the first-type doped semiconductor layer 324 is, for example, a P-type doped semiconductor layer, while the second-type doped semiconductor layer 328 is, for example, an N-type doped semiconductor layer. Alternatively, the first-type doped semiconductor layer 324 can be an N-type doped semiconductor layer and the second-type doped semiconductor layer 328 can be a P-type doped semiconductor layer as well. Both the above-described first-type doped semiconductor layer 324 and the second-type doped semiconductor layer 328 can be made of semiconductor compound material of the group III-V elements, which is, for example, gallium nitride (GaN), gallium phosphide (GaP) or gallium-arsenide-phosphide (GaAsP).

In an embodiment of the present invention, the LED 300 further includes a transparent conductive layer 350, wherein the transparent conductive layer 350 is disposed on the semiconductor layer 320, while the first electrode 330 and the second electrode 340 are disposed, for example, on the transparent conductive layer 350. The above-mentioned transparent conductive layer 350 is able to make the current applied to the first electrode 330 and the second electrode 340 evenly distributed on the semiconductor layer 320, which allows the LED 300 not only to have better electric behavior, but also to have higher luminous efficiency. The material of the transparent conductive layer 350 is, for example, indium tin oxide (ITO), indium zinc oxide (IZO), aluminum zinc oxide (AlznO), zinc oxide (ZnO), nickel oxide (NiO), nickel gold alloy (NiAu) or other transparent conductive material.

The above-described is the LED structure. The whole LED package is described in detail hereinafter.

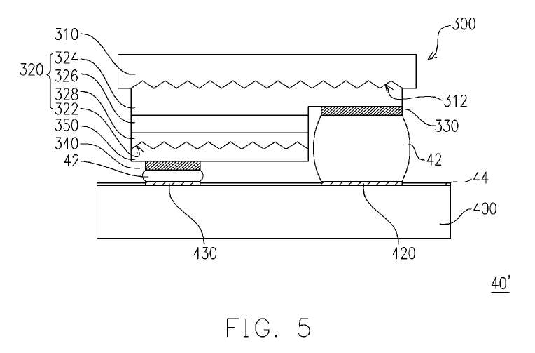

FIG. 4 is a schematic drawing of a LED package according to an embodiment of the present invention. Referring to FIG. 4, in a LED package 40 of the present invention, the LED 300 is electrically coupled to a carrier 400 through flip-chip interconnecting technology. The carrier 400 has a rough carrying surface 410 and includes a first contact pad 420 and a second contact pad 430 located on the rough carrying surface 410. Preferably, the rough carrying surface 410 is a surface with periodic or random concavities. The first electrode 330 and the second electrode 340 of the LED 300 face the carrier 400 and are electrically coupled to the first contact pad 420 and the second contact pad 430, respectively. The rough carrying surface 410 is made in the same processing as that for the rough surface 312.

In an embodiment of the present invention, the LED package 40 further includes two bumps 42, which are disposed on the first electrode 330 and the second electrode 340, respectively. The first electrode 330 and the second electrode 340 are electrically coupled to the first contact pad 420 and the second contact pad 430, respectively. The material of the above-described bumps is, for example, tin lead alloy (SnPb) or other appropriate materials. The above-described bumps can also be replaced by solder material.

Please refer to FIG. 4. In the embodiment, mainly by making the semiconductor layer 320 face a surface of the carrier 400 (the rough carrying surface 410) and the carrier 400 face a surface of the LED 300 (the rough surface 322), the light emitted from the light-emitting layer 326 is transmitted externally, so as to effectively improve the luminous efficiency of the LED package 40. Besides, the LED package with a rough surface 312 (the interface between the substrate 310 and the semiconductor layer 320) also contributes to effectively increasing the light extraction efficiency of the LED 300.

FIG. 5 is a schematic drawing of a LED package according to another embodiment of the present invention. Referring to FIG. 5, a LED package 40′ of the embodiment is similar to the above-described LED package 40 (as shown in FIG. 4), except that in the LED package 40′ of the embodiment, a reflective layer 44 is used to substitute the rough carrying surface 410 of the above-described LED package 40. The reflective layer 44 is disposed on the surface of the carrier 400 and the surface faces the LED 300. The LED package 40′ equipped with the reflective layer 44 also has good luminous efficiency.

In an embodiment, the reflective layer can be conformal to the rough carrying surface, so as to form a diffusive reflector for largely increasing the possibility for the light produced by the LED to be reflected by the reflective layer and radiate externally. In this way, the luminous efficiency of the LED package can be further improved.

Compared with the prior art where the light radiated by a LED tends to be reflected back inside the LED, to be absorbed by the internal material of the LED, the LED package of the present invention uses a plurality of rough surfaces or a combination of a reflective layer and rough surfaces to prevent the light radiated by the light-emitting layer from total reflection (TR) inside the LED, and further to prevent the outgoing light of the light-emitting layer from being reflected back to the LED. In this way, the light radiated by the light-emitting layer is able to be fully transmitted externally, such that the luminous efficiency of the LED package can be substantially improved.

It will be apparent to those skilled in the art that various modifications and variations can be made to the structure of the present invention without departing from the scope or spirit of the invention. In view of the foregoing, it is intended that the specification and examples to be considered as exemplary only, with a true scope and spirit of the invention being indicated by the following claims and their equivalents.

What is claimed is:

1. A light-emitting diode package (LED package), comprising:
a light-emitting diode (LED), comprising:
a substrate;
a semiconductor layer, disposed on the substrate and having a rough surface, wherein the semiconductor layer comprises a first-type doped semiconductor layer, a light-emitting layer and a second-type doped semiconductor layer and the light-emitting layer is located between the first-type doped semiconductor layer and the second-type doped semiconductor layer;
a first electrode, disposed on the first-type doped semiconductor layer and electrically coupled to the first-type doped semiconductor layer;
a second electrode, disposed on the second-type doped semiconductor layer and electrically coupled to the second-type doped semiconductor layer;
a carrier, having a first contact pad and a second contact pad disposed on a surface thereof, the first electrode and the second electrode of the LED being face the carrier and being electrically coupled to the first contact pad and the second contact pad, respectively; and
a reflective layer, disposed on a surface of the carrier facing the LED.

2. The LED package as recited in claim 1, wherein a surface of the substrate is a rough surface.

3. The LED package as recited in claim 1, further comprising two bumps disposed on the first electrode and the second electrode, respectively, wherein the first electrode and the second electrode are electrically coupled to the first contact pad and the second contact pad via the bumps, respectively.

4. The LED package as recited in claim 1, further comprising solder materials disposed on the first electrode and the second electrode, respectively, wherein the first electrode and the second electrode are electrically coupled to the first contact pad and the second contact pad via the solder materials, respectively.

5. The LED package as recited in claim 1, wherein the LED further comprises a transparent conductive layer disposed on the semiconductor layer and the first electrode and the second electrode is located on the transparent conductive layer.

6. The LED package as recited in claim 5, wherein a material of the transparent conductive layer comprises indium tin oxide (ITO), indium zinc oxide (IZO), aluminum zinc oxide (AlZnO), zinc oxide (ZnO), nickel oxide (NiO) or nickel gold alloy (NiAu).

7. The LED package as recited in claim 1, wherein the first-type doped semiconductor layer is disposed on the substrate, the light-emitting layer is disposed on the first-type doped semiconductor layer and the second-type doped semiconductor layer is disposed on the light-emitting layer.

8. The LED package as recited in claim 7, wherein the first-type doped semiconductor layer is a P-type doped semiconductor layer and the second-type doped semiconductor layer is a N-type doped semiconductor layer.

9. The LED package as recited in claim 7, wherein the first-type doped semiconductor layer is a N-type doped semiconductor layer and the second-type doped semiconductor layer is a P-type doped semiconductor layer.

10. The LED package as recited in claim 1, wherein a material of the substrate comprises sapphire, silicon carbide (6H—SiC or 4H—SiC), silicon (Si), zinc oxide (ZnO), gallium arsenide (GaAs), spinel (MgAl₂O₄) or a monocrystalline oxide with lattice constant close to that of nitride semiconductor.

11. The LED package as recited in claim 1, wherein the light-emitting layer comprises a multiple-quantum-well (MQW) light-emitting layer.

12. The LED package as recited in claim 1, wherein the carrier comprises a silicon substrate, an aluminum nitride substrate, a metal substrate, an alloy substrate or a ceramic substrate.

13. The LED package as recited in claim 1, wherein the carrier comprises a lead frame, a print circuit board (PCB) or a plastic lead chip carrier (PLCC).

14. A light-emitting diode package (LED package), comprising:
a light-emitting diode (LED), comprising:
a substrate;
a semiconductor layer, disposed on the substrate and having a rough surface, wherein the semiconductor layer comprises a first-type doped semiconductor layer, a light-emitting layer and a second-type doped semiconductor layer and the light-emitting layer is located between the first-type doped semiconductor layer and the second-type doped semiconductor layer;
a first electrode, disposed on the first-type doped semiconductor layer and electrically coupled to the first-type doped semiconductor layer;
a second electrode, disposed on the second-type doped semiconductor layer and electrically coupled to the second-type doped semiconductor layer;
a carrier, having a rough carrying surface and comprising a first contact pad and a second contact pad are disposed on the rough carrying surface, the first electrode and the second electrode of the LED being face the carrier and being electrically coupled to the first contact pad and the second contact pad, respectively.

15. The LED package as recited in claim 14, wherein a surface of the substrate is a rough surface.

16. The LED package as recited in claim 14, further comprising two bumps disposed on the first electrode and the second electrode, respectively, wherein the first electrode and the second electrode are electrically coupled to the first contact pad and the second contact pad via the bumps, respectively.

17. The LED package as recited in claim 14, further comprising solder materials disposed on the first electrode and the second electrode, respectively, wherein the first electrode and the second electrode are electrically coupled to the first contact pad and the second contact pad via the solder materials, respectively.

18. The LED package as recited in claim 14, wherein the LED further comprises a transparent conductive layer disposed on the semiconductor layer and the first electrode and the second electrode are located on the transparent conductive layer.

19. The LED package as recited in claim 14, wherein a material of the transparent conductive layer comprises indium tin oxide (ITO), indium zinc oxide (IZO), aluminum zinc oxide (AlZnO), zinc oxide (ZnO), nickel oxide (NiO) or nickel gold alloy (NiAu).

20. The LED package as recited in claim 14, wherein the first-type doped semiconductor layer is disposed on the substrate, the light-emitting layer is disposed on the first-type doped semiconductor layer and the second-type doped semiconductor layer is disposed on the light-emitting layer.

21. The LED package as recited in claim 20, wherein the first-type doped semiconductor layer is a P-type doped semiconductor layer and the second-type doped semiconductor layer is a N-type doped semiconductor layer.

22. The LED package as recited in claim 20, wherein the first-type doped semiconductor layer is a N-type doped semiconductor layer and the second-type doped semiconductor layer is a P-type doped semiconductor layer.

23. The LED package as recited in claim 14, wherein a material of the substrate comprises sapphire, silicon carbide (6H—SiC or 4H—SiC), silicon (Si), zinc oxide (ZnO), gallium arsenide (GaAs), spinel (MgAl₂O₄) or a monocrystalline oxide with lattice constant close to that of nitride semiconductor.

24. The LED package as recited in claim 14, wherein the light-emitting layer comprises a multiple-quantum-well (MQW) light-emitting layer.

25. The LED package as recited in claim 14, wherein the carrier comprises a silicon substrate, an aluminum nitride substrate, a metal substrate, an alloy substrate or a ceramic substrate.

26. The LED package as recited in claim 14, wherein the carrier comprises a lead frame, a print circuit board (PCB) or a plastic lead chip carrier (PLCC).
